(19) United States
(12) Patent Application Publication
(10) Pub. No.: US 2013/0127782 A1
(43) Pub. Date: May 23, 2013

(54) Surface-Integrated Keypad with Capacitive Analysis

(71) Applicants: Peter Lochner, Wollbach (DE); Steffen Neubauer, Hohenroth (DE); Stephan Braun, Bad Kissingen (DE); Dieter Schröder, Wulfershausen (DE); Alexander Metz, Sandberg (DE)

(72) Inventors: Peter Lochner, Wollbach (DE); Steffen Neubauer, Hohenroth (DE); Stephan Braun, Bad Kissingen (DE); Dieter Schröder, Wulfershausen (DE); Alexander Metz, Sandberg (DE)

(21) Appl. No.: 13/808,340

(22) PCT Filed: Jul. 25, 2011
(86) PCT No.: PCT/EP2011/062735

§ 371 Date: Jan. 4, 2013

(30) Foreign Application Priority Data
Jul. 30, 2010 (DE) 10 2010 038 721.5
Dec. 16, 2010 (DE) 10 2010 063 280.5

(51) Int. Cl. G06F 3/041

(52) U.S. Cl. CPC G06F 3/0414
USPC 345/174

(57) ABSTRACT

In accordance with 37 C.F.R. §§1.72(b) and 1.121(b), please amend the abstract as follows:

Operating element with a capacitive sensor, for activating a function display and/or backlighting system, for example in the case of approach, comprising the following: a button or pressure switch for a switching functionality, a layered film structure defining the operating surface, which is in operational engagement with the button or pressure switch in such a way that the button or pressure switch is actuated by pressing on the operating surface, characterized in that the layered film structure comprises at least one film, for example a polycarbonate film, and a conductive layer applied onto the film, preferably on the side of the film facing away from the operator, for providing at least one electrode of the capacitive sensor.

### CROSS-REFERENCE TO RELATED APPLICATIONS

This application is the U.S. National Phase of International Application No. PCT/EP2011/062735, filed Jul. 25, 2011, which, in turn, claims the benefit of German Application No. DE 10 2010 038 721.5, filed Jul. 30, 2010 and German Application No. DE 10 2010 063 280.5, filed Dec. 16, 2010, the contents of all of which are hereby incorporated by reference in their entirety as part of the present disclosure.

### FIELD OF THE INVENTION

The invention relates to an operating element for, for example, an instrument panel of a vehicle.

### BACKGROUND OF THE INVENTION

A variety of operating elements are known from the prior art. For example, pushbuttons or pressure switches are used for instrument panels of vehicles in order to activate or deactivate certain functions. It is disadvantageous, during the operation of operating element, for example in the dark or during driving, that a function of an operating element most frequently cannot be discerned.

US 2010/0038227 A1 proposes, for example, an operating element for a mobile phone which comprises a button and a capacitive sensor. Upon touching a key of the mobile phone, information on which function is activated by actuating the key is outputted via a loudspeaker. However, in the assembly proposed in US 2010/0038227 A1, erroneous diagnoses can occur with regard to which key the finger of the operator lies on.

### SUMMARY OF THE INVENTION

It is therefore the object of the present invention to provide an operating element as well as an operating assembly that avoids the above-mentioned draw-backs.

According to the invention, the object is achieved by an operating element with a capacitive sensor, for activating at least one of a function display and a backlighting system in the case of approach, comprising a button or pressure switch for switching functionality, and a layered film structure defining an operating surface in operational engagement with the button or pressure switch such that the button or pressure switch is actuated by pressing on the operating surface, wherein the layered film structure comprises at least one film and a conductive layer applied onto the at least one film defining at least one electrode of the capacitive sensor. In some embodiments, the conductive layer comprises at least one of a conductive metal, such as silver for example, and a conductive polymer. In some embodiments, the operating element may be used in an instrument panel of a vehicle. In some embodiments, an operating assembly, comprising at least one operating element coupled to at least one informing unit, may be used in an instrument panel of a vehicle. Other advantageous embodiments become apparent from the following description. However, the individual features of the embodiments described are not limited thereto but may be combined with one another and with other features to constitute other embodiments.

An operating element is proposed with a capacitive sensor for activating a function display and/or backlighting system, for example in the case of an approach, the operating control comprising the following: one or more buttons or pressure switches for a switching functionality, a layered film structure defining the operating surface, which is in operational engagement with the button or pressure switch in such a way that the button or pressure switch is actuated by pressing on the operating surface. It is characterized in that the layered film structure comprises at least one film, for example a polycarbonate film, and a conductive layer applied onto the film, preferably on the side of the film facing away from the operator, for providing at least one electrode of the capacitive sensor. Advantageously, the layered film structure serves for covering the button in order thus to protect it from corrosion and the effect of dirt. Advantageously, this protective film is used at the same time as a carrier for the electrodes of the capacity proximity sensor.

Buttons or pressure switches within the sense of the invention are understood by the person skilled in the art to be all tactile and switching devices that can be operated manually. The terms buttons, switches and pressure switches are hereinafter used synonymously. The terms buttons, switches and pressure switches can stand for break or make contacts. Furthermore, aforesaid terms can be understood to mean an industrial pushbutton, membrane keys, silicone keypads, Hall buttons, Hall switches, capacitive buttons, piezo buttons, toggle switches, rocker switches, pressure switches, latching switches, slide switches, rotary switches, step switches, momentary-contact switches, foot switches, key-operated switches or also touchscreens or touchpads.

An approach within the sense of the invention is understood by the person skilled in the art to mean a movement of an object, for example a finger or a hand, in the direction of the operating element. Preferably, the capacitive sensor detects an approach if the distance of the approaching object from the operating element falls below about 10 cm, more preferably about 5 cm, still more preferably about 1 cm, particularly preferably about 0.2 cm. In another embodiment, it is provided that the operator, for example, has to touch the operating element in order for an approach to be detected by the capacitive sensor. Preferably, the capacitive sensor is one of the type with which two switching states are associated. In a further preferred embodiment, the capacitive sensor remains activated until the object that has approached has moved away by a defined distance, preferably about 10 cm, more preferably about 5 cm, still more preferably about 1 cm, particularly preferably about 0.2 cm.

In another embodiment, a capacitive sensor with more than two switching states is provided. These sensors are advantageous in that they assign several functions to an operating element or a capacitive sensor, depending on the signal strength. Moreover, a verification is easily possible by weighting the sensor signals of different capacitive sensors that are disposed close to one another.

Where the term “about” is used in the present invention, this specifies a tolerance range which the person skilled in the art working in the present field considers to be common. In particular, the term “about” is to be understood to mean a tolerance range of up to +/−20%, preferably up to +/−10%.

In a preferred embodiment, it is provided that the capacitive sensor is associated with the button or pressure switch. Preferably, the capacitive sensor—in the actuation direction of the button or pressure switch—is located above the button or pressure switch, so that the capacitive sensor outputs an approach signal if an operator approaches the button of the operating element.

The proposed operating element is advantageous in that erroneous detections in the case of an approach towards the operating element are largely avoided. In particular, this can be ascribed to the fact that the capacitive sensor is disposed in the layered film structure forming the operating surface. Thus, the capacitive sensor is disposed closer to the operator than in embodiments known from the prior art. It was found that a detection of those buttons approached by an operator can be carried out reliably, even in the case of operating elements that are disposed very close to one another or adjacent to one another. Another advantage is that a deformation of the layered film structure takes place upon touching or actuation of the button. According to a further development, further information, such as a contact pressure, can be gathered from this deformation, which in one embodiment is detected by the capacitive sensor.

In one embodiment, for example, a backlighting of the operating element is provided if the operator approaches the operating element, for example comes closer to it than 5 cm. For example, this enables the illumination of several operating elements located in the vicinity of the finger of the operator. In one variation, it is provided that the operator receives information on the function of the operating element upon touching the operating element, for example acoustically or via a display, preferably an overhead display. The output of information on the function of the operating element is particularly advantageous in the case of freely programmable operating elements. In another embodiment, it is provided that another function is triggered when the layered film structure is deformed, preferably prior to the button being actuated. Preferably, a verification is carried out through the deformation of the layered film structure of whether the correct function assigned to the operating element was displayed.

In a preferred embodiment, it is provided that the layered film structure comprises an elastic, preferably non-conductive, layer, for example consisting of natural rubber, synthetic rubber, preferably of thermoplastic elastomer. In another embodiment, the layered film structure comprises a layer which at least comprises silicone.

Preferably, an elastic, non-conductive layer adjacent to the film and/or the conductive coating thereof is provided underneath the film, which is applied to the film by back injection. In one variation, it is provided that the elastic, non-conductive layer is disposed between the button and the film. Preferably, the conductive layer providing the electrode is disposed between the film and the elastic layer.

According to one embodiment, the elastic non-conductive layer and the film, or the conductive layer thereof, are glued together. Furthermore, one embodiment provides that the elastic non-conductive layer be arranged in a loose touching contact with the film between the button and the film, i.e. without a connection by positive fit. Moreover, it is provided in one embodiment that the rubber layer is vulcanized onto the film.

The elastic, non-conductive layer advantageously has a damping effect during the mechanical action on the button, and on the other hand, it serves for additionally protecting the conductive coating from corrosion and mechanical stress. Furthermore, the elastic layer provides a softer and more comfortable haptic impression when the operating element is actuated. Preferably, the elastic layer comprises a thickened portion in the area of the button, i.e. in the area in which the elastic layer touches the button at least when it is actuated, the cross section of the elastic layer in the direction defined by the actuation direction of the button is greater than in an area of the elastic layer surrounding the button.

Preferably, the conductive layer comprises silver or a conductive polymer. Preferably, this is a transparent or translucent polymer. Preferably, the conductive layer is applied by printing. In another embodiment, the conductive layer comprises a copper alloy and/or a gold alloy. Particularly conductive metals allow for a small materials expenditure, or a thinner application of materials on the film. Materials that are flexible and, particularly preferably, have a similar material expansion coefficient as the material of the film used, are particularly preferred for the conductive layer.

For example, the conductive layer is not applied to the film over its entire surface, but, for example, in the form of strips and/or electrode surfaces insulated from one another.

In one embodiment, the film comprises at least one material selected from a group that at least comprises polyester, preferably polycarbonates, polyethylene terephthalate, polyethylene naphthalate and/or polyethylene naphthalate.

In another embodiment, it is provided that the layered film structure comprises at least the film, wherein the film comprises a thermoplastic material. Furthermore, one embodiment provides that the layered film structure comprises at least the conductive layer, wherein the conductive layer is printed on the film. For example, it is provided that the layered film structure, starting from the side facing towards the operator, comprises at least the following layers: the film, the film consisting of a thermoplastic material, the conductive layer, wherein the conductive layer is printed on the film, the elastic, non-conductive layer, wherein the elastic layer is applied to the film on which the conductive layer is printed.

In a particularly preferred embodiment, the layers of the layered film structure cannot be separated in a non-destructive manner.

In another embodiment, the layered film structure is connected to a carrier component, for example consisting of a rigid plastic, in a positive fit.

The invention further relates to an operating assembly comprising at least one operating element as described above. The operating assembly is coupled to at least one informing unit, wherein the informing unit provides information on at least a sensor state of at least one capacitive sensor of the operating element.

In one embodiment, it is provided that the informing unit provides information on a function of the button or pressure switch which an operator has approached. This is advantageous in that, particularly if the operating assembly is used in a vehicle, the driver does not have to take his eyes away from the traffic, but is informed in the case of blind operation, for example by means of an overhead display or a display in an instrument cluster, about the function of the operating element that his finger has approached.

An informing unit within the sense of the invention can be an optical, acoustical or haptic outputting element. Particularly preferably, the informing unit is a loudspeaker, a display, preferably an overhead display or a vibrator. Particularly preferably, the informing unit is coupled with a data processing unit, which, depending on the signals from the operating elements, outputs stored notifications or information to the operator via the informing unit.

In another embodiment, it is provided that the operating assembly has a haptically detectable structure, by means of which the operating element can be discerned from a surrounding surface. Preferably, the operating element is raised from the surrounding surface. In another embodiment, the operating element forms a depression. In another embodiment, it is provided that adjacent operating elements are haptically separated from one another by a shaping of the film, or of the layered film structure. In a particularly preferred embodiment, a haptic and/or visual separation of the operating element is not discernible. This configuration is possible primarily because, by means of the proposed operating assembly, a differentiation between the operating elements is possible by means of the informing unit.

Another idea of the invention relates to a use of an operating element as de-scribed above, or of an operating assembly as described above, in an instrument panel of a vehicle. For example, the vehicle can be a passenger vehicle, a truck, a motorcycle, a boat, a ship or another watercraft. Moreover, one embodiment provides that the vehicle is an airplane or a helicopter.

Other advantageous embodiments become apparent from the following drawings. However, the developments depicted therein are not to be construed to be limiting; rather, the features described therein can be combined with one another and with the above-described features to constitute further embodiments. Furthermore, it should be noted that reference numerals indicated in the description of the Figures do not limit the scope of protection of the present invention but merely refer to the exemplary embodiments shown in the Figures. Identical parts or parts that have the same function have the same reference numerals below.

### BRIEF DESCRIPTION OF THE DRAWINGS

FIG. 1 shows a schematic exploded view of an operating assembly; and

FIG. 2 shows a schematic cross-sectional view of the layered film structure.

### DETAILED DESCRIPTION OF EMBODIMENTS OF THE INVENTION

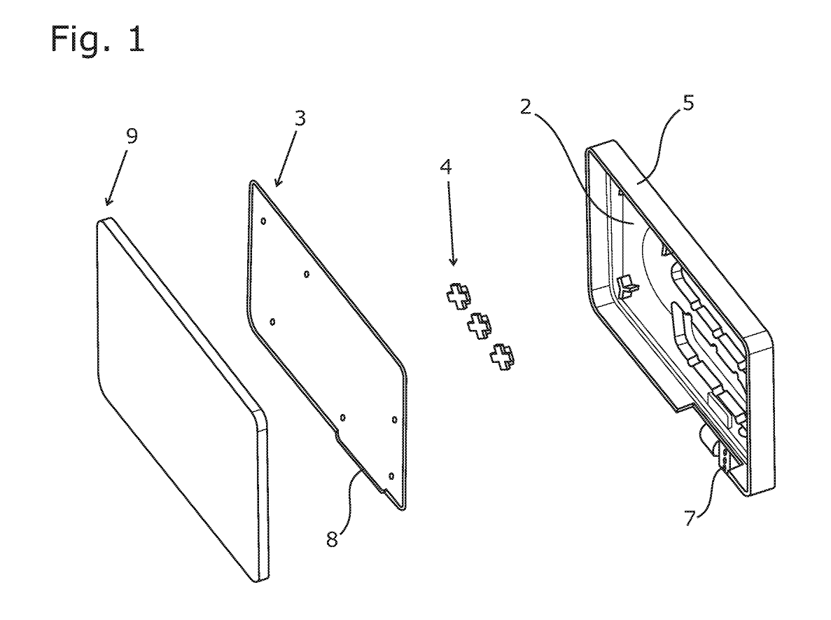

FIG. 1 shows a schematic exploded view of an operating assembly 1. The operating assembly 1 comprises a layered film structure 2 as well as buttons 4 disposed on a circuit board 3. Moreover, contact elements 7, 8 are provided on the layered film structure which contact correspondingly assigned contacts of the circuit board 3 and with which the layered film structure 2, or the conductive layer integrated into the layered film structure 2, can be connected to a data processing unit not shown herein, for example an ECU. The layered film structure 2 comprises a film with conductor paths printed thereon and an elastic, non-conductive layer. The layered film structure 2 is connected by positive fit to a frame-shaped carrier component stabilizing the layered film structure. A cap 9 closes off the operating element 1 on the side thereof facing away from the operator.

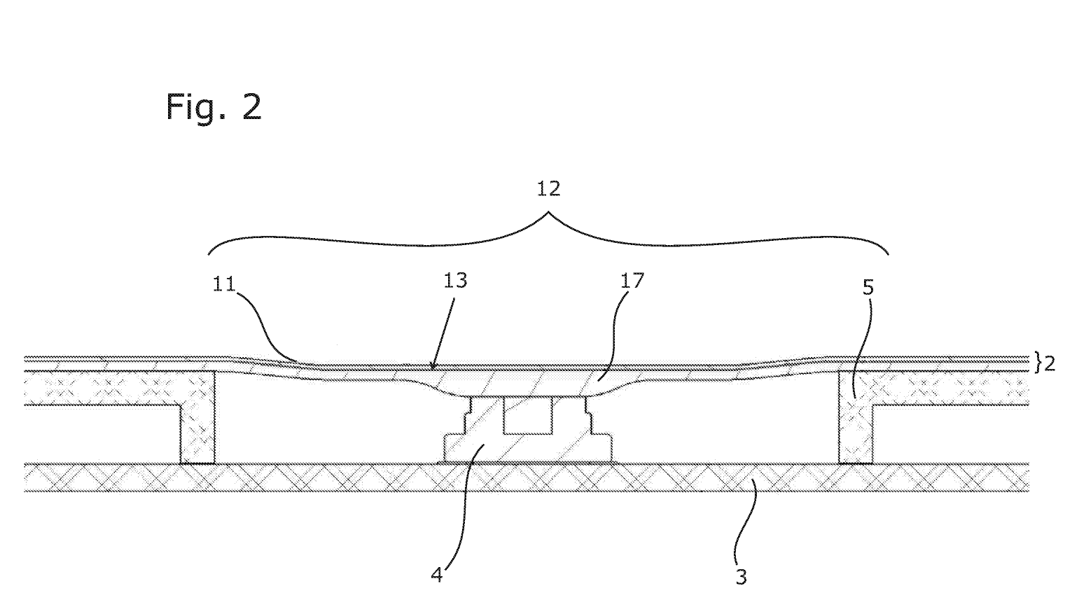

FIG. 2 shows a schematic cross-sectional view of the layered film structure 2. The layered film structure comprises a film 11 consisting of a polycarbonate. The film forms an operating surface 12. On the rear of the operating surface 12, a conductive layer 13 in the form of conductor paths or electrodes is printed on the film 11 which form capacitive electrodes for associated sensors. In order to protect the conductive layer 13 to improve the haptics of the individual operating elements 15, which are here indicated by dashed lines, a non-conductive, elastic layer 17 is applied to the film 11. The layered film structure 2 is connected by positive fit to a carrier component 5. A button 4 is disposed under the layered film structure 2 and in touching contact therewith, whose switching state is changed when it is actuated. The button 4 is contacted via a circuit board 3.

1. An operating element with a capacitive sensor, for activating at least one of a function display and a backlighting system in the case of approach, comprising:
a button or pressure switch for switching functionality, and
a layered film structure defining an operating surface in operational engagement with the button or pressure switch such that the button or pressure switch is actuated by pressing on the operating surface, wherein the layered film structure comprises at least one film polycarbonate film, and a conductive layer applied onto the at least one film (11), defining at least one electrode of the capacitive sensor.

2. An operating element as defined in claim 1, wherein the capacitive sensor is operatively associated with the button or pressure switch.

3. An operating element as defined in claim 1, wherein the layered film structure further comprises an elastic, layer.

4. An operating element as defined in claim 3, wherein the elastic, layer is disposed between the button and the at least one film.

5. An operating element as defined in claim 1, wherein the conductive layer is applied onto the at least one film by printing.

6. An operating element as defined in claim 1, wherein the at least one film comprises a thermoplastic material.

7. An operating element as defined in claim 1, wherein the conductive layer comprises at least one of a conductive metal, and a conductive polymer.

8. An operating assembly comprising:
at least one operating element with a capacitive sensor, for activating at least one of a function display and a backlighting system in the case of approach, comprising a button or pressure switch for switching functionality, and a layered film structure defining an operating surface in operational engagement with the button or pressure switch such that the button or pressure switch is actuated by pressing on the operating surface, wherein the layered film structure comprises at least one film and a conductive layer applied onto the at least one film defining at least one electrode of the capacitive sensor; and
at least one informing unit, wherein the at least one operating element is coupled to the at least one informing unit and said at least one informing unit is adapted to provide information about at least one sensor state of each capacitive sensor of each of the at least one operating element.

9. An operating assembly as defined in claim 8, wherein the at least one informing unit is adapted to provide information about a function of the button or pressure switch which an operator has approached.

10. An operating assembly as defined in claim 8, wherein the operating assembly includes a haptically detectable structure for discerning the operating element from a surrounding surface.

11. (canceled)

12. An operating element as defined in claim 1, wherein the at least one film comprises a polycarbonate film.

13. An operating element as defined in claim 1, wherein the conductive layer is applied on a side of the at least one film facing away from an operator.

14. An operating element as defined in claim 3, wherein the elastic layer comprises a non-conductive layer.

15. An operating element as defined in claim 7, wherein the conductive metal comprises silver.
